(19) United States
(12) Patent Application Publication
(10) Pub. No.: US 2008/0157090 A1
(43) Pub. Date: Jul. 3, 2008

(54) Transplanted epitaxial regrowth for fabricating large area substrates for electronic devices

(76) Inventors: Darren Brent Thomson, Ellicott City, MD (US); Jeffrey D. Hartman, Severn, MD (US)

Correspondence Address: ANDREWS KURTH LLP;Intellectual Property Department, Suite 1100, 1350 I Street, NW, Washington, DC, 20005, US

(21) Appl. No.: 11/646,347

(22) Filed: Dec. 28, 2006

(51) Int. Cl. H01L 31/112

(52) U.S. Cl. 257/66; 117/36; 117/952

(57) ABSTRACT

An epitaxial layer regrowth method and device. A single crystal seed layer is deposited on a support wafer. An exfoliation layer is implanted in the single crystal seed layer. Trenches are etched in a portion of the single crystal seed layer and a portion of the exfoliation layer. The single crystal seed layer, on the support wafer, is bonded to a substrate. The support wafer and the exfoliation layer are removed leaving behind one or more single crystal seeds, generated from the single crystal seed layer, on the substrate. A first epitaxial layer is grown on the substrate from the single crystal seeds and a device layer is grown on the first epitaxial layer. In an alternative embodiment, a single crystal seed layer is deposited on a support wafer comprising an etch stop.

### FIELD OF THE INVENTION

The invention relates generally to electronic devices, specifically to methods and devices formed by transplanted epitaxial regrowth.

### BACKGROUND OF THE INVENTION

Gallium nitride (GaN) and its alloys are used to fabricate devices for high power and high frequency electronic applications including radar, electronic warfare (EW), and communications systems. Currently, single crystal silicon carbide (SiC) substrates are used for GaN growth because of the high thermal conductivity of SiC and relatively small lattice mismatch (approximately 3%) between SiC and GaN. However, SiC is expensive and unavailable in large area wafers. Alternatively, GaN has been grown on silicon, which is relatively inexpensive and is available in larger area wafers, such as wafers with diameters of 100 mm or larger. Growth of epitaxial GaN layers on silicon substrates has proven to be more difficult than on SiC, due primarily to larger mismatches both in crystal lattice and in thermal expansion, which leads to stressed films. In addition, GaN devices on silicon substrates may suffer from inferior crystal quality and difficulty in maintaining an electrically insulating substrate—a requirement for efficient radio frequency (RF) performance. Furthermore, GaN on silicon devices are designed and operated at lower power densities because the thermal conductivity of silicon limits heat dissipation.

### SUMMARY OF THE INVENTION

An epitaxial layer regrowth method and device using an exfoliation layer. A single crystal seed layer is deposited on a support wafer. An exfoliation layer is implanted in the single crystal seed layer. Trenches are etched in a portion of the single crystal seed layer and a portion of the exfoliation layer. The single crystal seed layer, on the support wafer, is bonded to a substrate. The support wafer and the exfoliation layer are removed leaving behind one or more single crystal seeds, generated from the single crystal seed layer, on the substrate. A first epitaxial layer is grown on the substrate from the single crystal seeds and a device layer is grown on the first epitaxial layer.

An epitaxial layer regrowth method and device using an etch stop layer. A single crystal seed layer is deposited on a support wafer containing an etch stop. Trenches are etched in a portion of the single crystal seed layer and a portion of the etch stop layer. The single crystal seed layer, on the support wafer, is bonded to a substrate. The support wafer and the etch stop layer are removed leaving behind one or more single crystal seeds, generated from the single crystal seed layer, on the substrate. A first epitaxial layer is grown on the substrate from the single crystal seeds and a device layer is grown on the first epitaxial layer.

### BRIEF DESCRIPTION OF THE DRAWINGS

FIG. 1 is a diagrammatic representation of a single crystal seed layer deposited on a support wafer in accordance with an embodiment.

FIG. 2 illustrates an implanted exfoliation layer in accordance with an embodiment.

FIG. 3 illustrates trench etching in accordance with an embodiment.

FIG. 4 illustrates bonding of the single crystal seed layer, on the support wafer, to a large area substrate, in accordance with an embodiment.

FIG. 5 illustrates single crystal seeds on the large area substrate, in accordance with an embodiment.

FIG. 6 illustrates a device fabricated using epitaxial regrowth on the large area substrate, in accordance with an embodiment.

FIG. 7 is a flow chart illustrating an epitaxial layer regrowth method, in accordance with an embodiment.

### DETAILED DESCRIPTION

Large area substrates suitable for fabricating high performance, for example, gallium nitride (GaN) based devices are described. In an embodiment, using wafer bonding techniques, small single-crystal GaN, aluminum nitride (AlN), other materials, or combinations thereof, seed templates are “transplanted” onto an inexpensive, readily available, large area substrate, such as polycrystalline silicon carbide (SiC) or other substrate types such as polycrystalline AlN or polycrystalline silicon with/without dielectrics. GaN or other material is then regrown from the transplanted seed templates, on the large area substrate. Various device structures can then be grown on the regrown layer. The described methods may enable the production of, for example, GaN radio frequency (RF) devices on low cost, large area substrates with high thermal conductivity and high electrical resistivity.

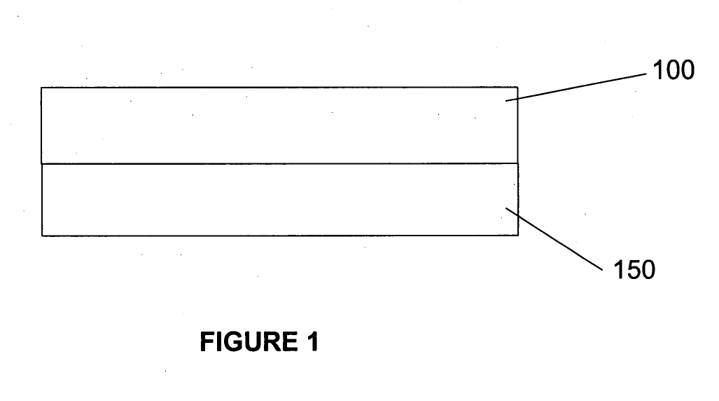

FIGS. 1-6 diagrammatically illustrate a transplanted epitaxial regrowth method in accordance with an embodiment. FIG. 1 shows a single crystal seed layer 100 deposited on a support wafer 150. The single crystal material for layer 100 may be, for example, GaN, AlN, SiC, aluminum gallium nitride (AlGaN), indium gallium nitride (InGaN), indium phosphide (InP), gallium arsenide (GaAs), or any combination thereof. The support wafer 150 may be made of, for example, silicon, silicon carbide, gallium nitride, aluminum nitride, zinc oxide, or sapphire.

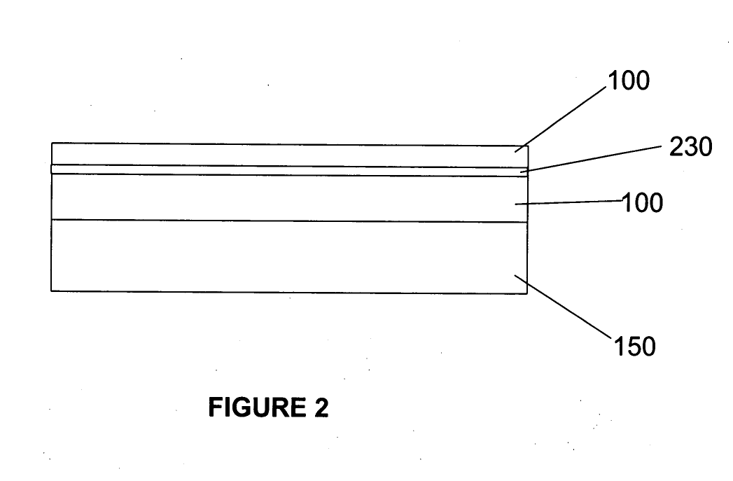

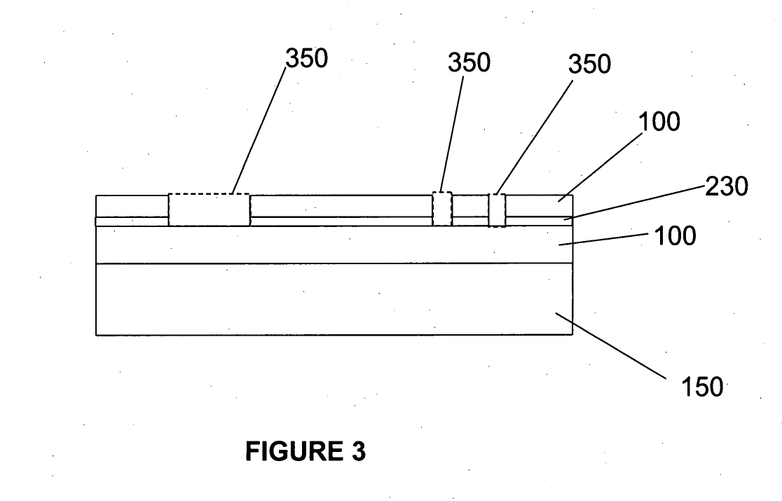

As shown in FIG. 2, the layer 100 may be implanted with an exfoliation layer, such as hydrogen (H₂) and/or helium (He) 230, in preparation for a layer exfoliation procedure described below. In an alternate method, layer 100 may be deposited on a substrate including an etch stop layer (not shown). As shown in FIG. 3, trenches 350 may be etched into the layer 100. In an embodiment, trenches 350 may be etched beyond the H₂ and/or He implant layer 230, in layer 100. The trenches 350 may be employed to transfer the seed material 100 in a specific pattern for the subsequent epitaxial growth. The specific pattern for the seed material 100 may depend on the type of device to be fabricated. Trenches 350 may also enhance a wafer bonding process (described below) by preventing the formation of air pockets between the bonded materials.

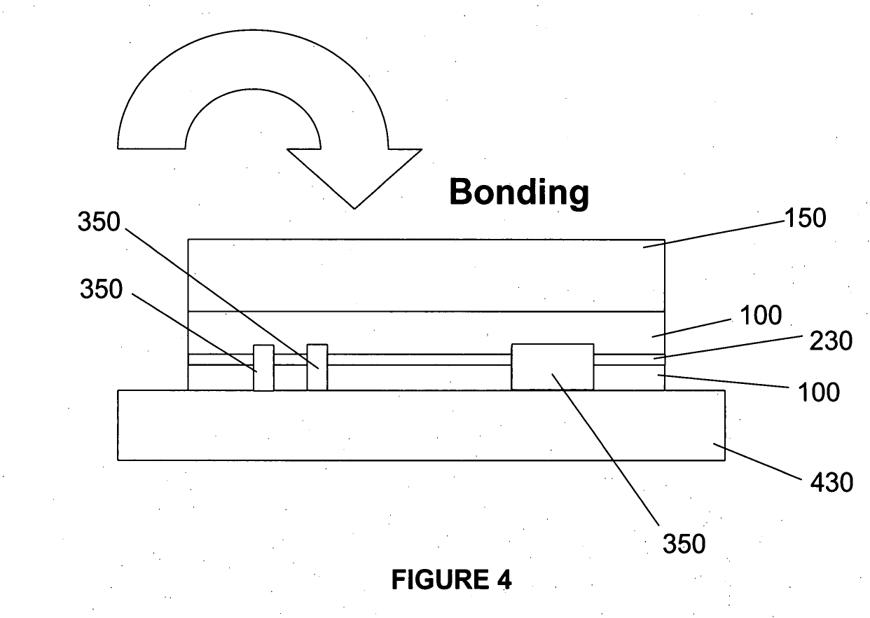

As shown in FIG. 4, the trenched seed layer 100, on the support wafer 150, may be bonded to a large area substrate 430. The large area substrate 430 may be made of a polycrystalline material or a single crystalline material. The large area substrate 430 may be made of, for example, SiC, diamond, AlN, boron nitride (BN), graphite, sapphire, silicon, silicon dioxide (SiO₂), silicon nitride, or any combination thereof. The substrate 430 may include material having a high thermal conductivity or it may be thermally insulating. The substrate material may be electrically conducting or electrically insulating. Moreover, the substrate material may be amorphous and/or may be optically transparent. In an embodiment, the bond between the seed layer 100 and the substrate 430 may be an electrically conducting bond. In other words, electricity may be able to flow from the substrate 430 to the seed layer 100 through the bonding shown in FIG. 4.

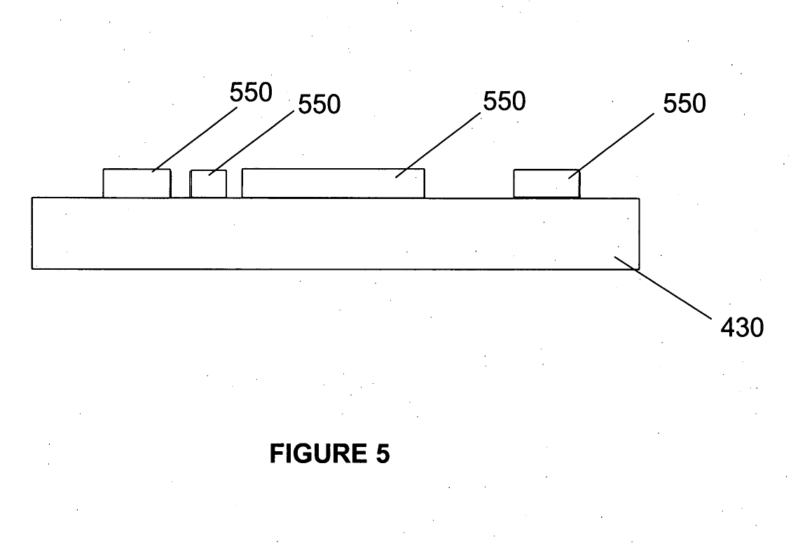

As shown in FIG. 5, the bonded assembly of FIG. 4 is heated for layer exfoliation to remove the support wafer 150, leaving behind portions of the seed layer 100 as single crystal seeds 550, bonded to the large area substrate 430. The single crystal seeds 550 may be made of, for example, GaN, AlN, SiC, AlGaN, InGaN, InP, GaAs, or any combination thereof. In the alternate embodiment using an etch stop, the support layer may be removed through grinding, lapping, wet etching or dry etching.

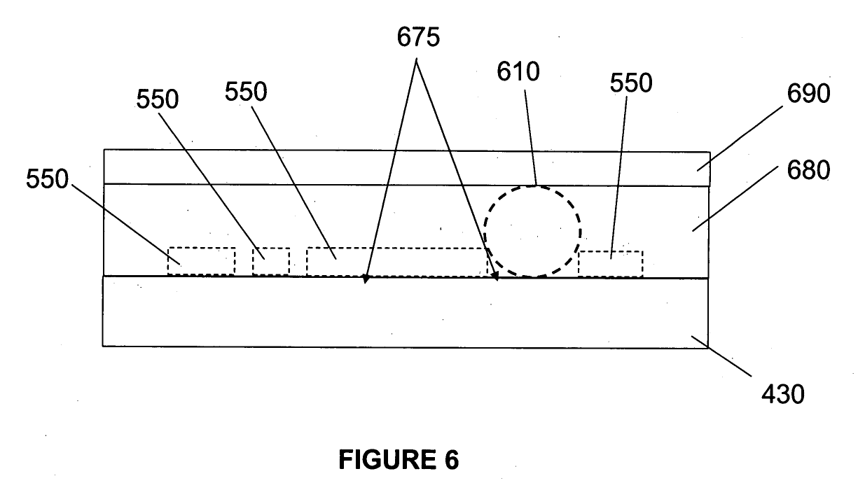

As shown in FIG. 6, the epitaxial regrowth layer 680 is grown from the seeds 550. The layer 680 may be, for example, a GaN layer regrown from GaN template seeds. The epitaxial regrowth layer 680 may be of other materials, such as AlN, AlGaN, InGaN, SiC, InP, GaAs, gallium antimonide (GaSb), InAs, AlAs, or any combination thereof. As can be seen, the lateral regrowth of layer 680 fills in voids on substrate 430 and produces the highest quality material with very low defects, as shown by the dotted circle 610. Also, the nitride layers (e.g., GaN), shown by arrows 675, directly contact the substrate 430 for best heat dissipation and thermal conductivity, without air gaps or thermal barriers.

As shown in FIG. 6, other epitaxial layers, such as a device layer 690 or other layers, may be grown on epitaxial regrowth layer 680. The device layer(s) 690 may include, for example, a field effect transistor (FET), a light emitting diode (LED), a laser diode, a photo detector, other circuitry or devices, or any combination thereof.

In an embodiment, a single crystal silicon layer (omitted) may be bonded to the device layer 690. Further fabrication of complementary metal oxide semiconductor (CMOS) devices is possible on the silicon layer. Other devices that may be formed may include, for example, a GaN high electron mobility transistor (HEMT), also called heterostructure FET, or heterogeneous integration of GaN HEMT with silicon CMOS.

In accordance with an embodiment, the epitaxial regrowth material on substrate, for example, GaN regrown from seed templates bonded to a poly-SiC substrate, may provide a device wafer that can be up to 300 mm in diameter. Other features of such a device wafer may be, for example, low cost, improved heat dissipation, reduced parasitic RF losses due to low electrical resistivity, higher quality of GaN layers based on lattice mismatch. The quality of the GaN layers may be improved in the laterally overgrown regions.

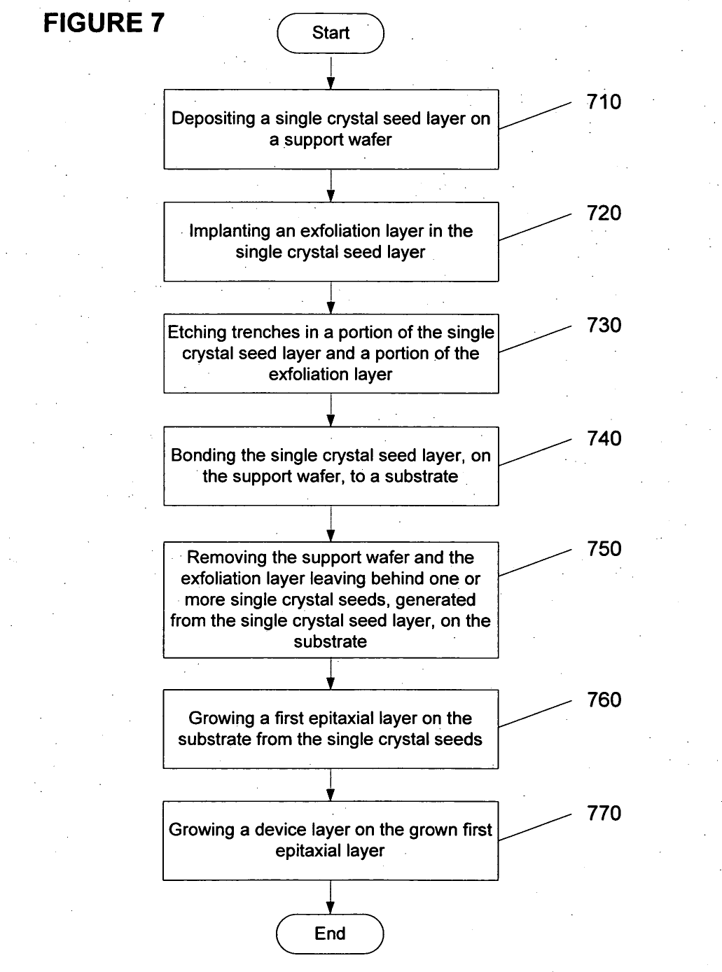

FIG. 7 is a flow chart illustrating an epitaxial layer regrowth method, in accordance with an embodiment. A single crystal seed layer is deposited on a support wafer, as shown in 710. An exfoliation layer is implanted in the single crystal seed layer, as shown in 720. Trenches are etched in a portion of the single crystal seed layer and a portion of the exfoliation layer, as shown in 730. The single crystal seed layer, on the support wafer, is bonded to a substrate, as shown in 740. The support wafer and the exfoliation layer is removed leaving behind one or more single crystal seeds, generated from the single crystal seed layer, on the substrate, as shown in 750. A first epitaxial layer is grown on the substrate from the single crystal seeds, as shown in 760. Device layers can then be grown on the first epitaxial layer, as shown in 770.

In an embodiment, an epitaxial layer regrowth method includes an etch stop layer. A single crystal seed layer is deposited on a support wafer containing an etch stop. Trenches are etched in a portion of the single crystal seed layer and a portion of the etch stop layer. The single crystal seed layer, on the support wafer, is bonded to a substrate. The support wafer and the etch stop layer are removed leaving behind one or more single crystal seeds, generated from the single crystal seed layer, on the substrate. A first epitaxial layer is grown on the substrate from the single crystal seeds and a device layer is grown on the first epitaxial layer. Optionally, only the support wafer may be removed leaving behind the etch stop layer and the one or more single crystal seeds.

The etch stop layer may either be incorporated within the support wafer, such as a silicon-on-insulator wafer, implanted into the wafer, or may be deposited as the first layer prior to the single crystal seed layer. The etch stop layer has a lower etch rate than the bulk of the support wafer which is being removed. For a silicon on insulator substrate, for example, certain wet and dry etches preferentially etch silicon over buried silicon oxide. Examples of wet etches include, but are not limited to, potassium hydroxide or tetramethylammonium hydroxide for silicon etch with a silicon oxide etch stop. Dry etches may include, but are not limited to, xenon difluoride (XeF₂), sulfur hexafluoride (SF₆), carbon hydro-trifluoride (CHF₃), chlorine gas (Cl₂), and hydrogen bromide (HBr). In another embodiment, the etch stop layer may be created by implanting species into the support wafer. Examples of implanted species include carbon, boron, germanium, and oxygen. Optionally or additionally, an etch stop may be deposited as the first layer for epitaxial growth. For example, aluminum nitride may be deposited prior to the gallium nitride growth. This layer will then be used as an etch stop during substrate removal.

Various devices can be fabricated using the methods described herein, such as devices used for high power and high frequency electronic applications including radar, electronic warfare (EW), and communications systems. Large area wafers with diameters of 100 mm or larger can be fabricated in accordance with an embodiment of the present invention.

Several embodiments of the present invention are specifically illustrated and/or described herein. However, it will be appreciated that modifications and variations of the present invention are covered by the above teachings and within the purview of the appended claims without departing from the spirit and intended scope of the invention.

What is claimed is:

1. An epitaxial layer regrowth method, comprising:
depositing a single crystal seed layer on a support wafer;
implanting an exfoliation layer in the single crystal seed layer;
etching trenches in a portion of the single crystal seed layer and a portion of the exfoliation layer;
bonding the single crystal seed layer, on the support wafer, to a substrate;
removing the support wafer and the exfoliation layer leaving behind one or more single crystal seeds, generated from the single crystal seed layer, on the substrate;
growing a first epitaxial layer on the substrate from the single crystal seeds; and
growing a device layer on the grown first epitaxial layer.

2. The method of claim 1, further comprises:
growing a second epitaxial layer on the first epitaxial layer.

3. The method of claim 1, wherein growing the device layer comprises:
growing an epitaxial layer forming one or more of a field effect transistor, a light emitting diode, a laser diode, and a photodetector.

4. The method of claim 1, further comprises:
bonding a single crystal silicon layer to the device layer;
fabricating complementary metal oxide semiconductor devices on the bonded single crystal silicon layer.

5. The method of claim 1, wherein the substrate is one of a polycrystalline and a single crystalline.

6. The method of claim 1, further comprising:
forming an electrically insulating bond interface between the substrate and the one or more single crystal seeds.

7. The method of claim 1, wherein the support wafer comprises an etch stop layer.

8. The method of claim 1, further comprising:
forming an electrically conducting bond interface between the substrate and the one or more single crystal seeds.

9. The method of claim 1, wherein the substrate includes a layer comprising one or more of silicon carbide, diamond, aluminum nitride, boron nitride, graphite, sapphire, silicon, silicon dioxide, and silicon nitride.

10. The method of claim 1, wherein the single crystal seed layer comprising one or more of gallium nitride, aluminum nitride, silicon carbide, aluminum gallium nitride, indium gallium nitride, indium phosphide, and gallium arsenide.

11. The method of claim 1, wherein the first epitaxial layer comprises one or more of gallium nitride, aluminum nitride, indium nitride, silicon carbide, indium phosphide, gallium arsenide, and gallium antimonide.

12. The method of claim 1, wherein the exfoliation layer comprising one or more of helium, boron, and hydrogen.

13. An device comprising:
a substrate;
a first gallium nitride layer grown on the substrate from a gallium nitride single crystal seed layer or an aluminum nitride single crystal seed layer; and
a device layer grown on the first epitaxial layer, wherein the first gallium nitride layer grown forms a bond with the substrate and the device layer comprises one or more of the following devices:
a field effect transistor; and
a light emitting diode.

14. The device of claim 13, further comprising:
a second epitaxial layer formed on the first gallium nitride layer.

15. The device of claim 13, wherein the device layer further comprises one or more of:
a laser diode and a photodetector.

16. The device of claim 13, further comprising:
a single crystal silicon layer on the device layer;
a complementary metal oxide semiconductor device fabricated with the single crystal silicon layer.

17. The device of claim 13, wherein the substrate comprises from one or more of a polycrystalline material, a thermally conductive material, an optically transparent material, a single crystalline material, an amorphous material, an electrically conductive material, and an electrically insulating material.

18. The device of claim 13, wherein the substrate further comprises one or more of diamond, aluminum nitride, boron nitride, graphite, sapphire, silicon, silicon dioxide, silicon carbide, and silicon nitride.

19. The device of claim 13, wherein the single crystal seed layer further comprises one or more of silicon carbide, aluminum gallium nitride, indium gallium nitride, indium phosphide, and gallium arsenide.

20. The device of claim 13, wherein the first layer further comprises one or more of aluminum nitride, silicon carbide, aluminum gallium nitride, indium gallium nitride, indium phosphide, gallium arsenide, and gallium antimonide.

21. An epitaxial layer regrowth method, comprising:
depositing a gallium nitride single crystal seed layer on a support wafer;
implanting an hydrogen exfoliation layer in the single crystal seed layer;
etching trenches in a portion of the single crystal seed layer and a portion of the exfoliation layer;
bonding the single crystal seed layer, on the support wafer, to a silicon carbide substrate;
removing the support wafer and the hydrogen exfoliation layer leaving behind one or more gallium nitride single crystal seeds, generated from the single crystal gallium nitride seed layer, on the substrate;
growing a gallium nitride epitaxial layer on the substrate from the gallium nitride single crystal seeds; and
growing a device layer on the grown gallium nitride epitaxial layer.

22. The method of claim 21, further comprises:
growing a second epitaxial layer on the first epitaxial layer.

23. The method of claim 21, wherein growing the device layer comprises:
growing an epitaxial layer forming one or more of: a field effect transistor, a light emitting diode, a laser diode and a photodetector.

24. The method of claim 21, further comprises:
bonding of a single crystal silicon layer to the device layer;
fabricating complementary metal oxide semiconductor devices with the bonded single crystal silicon layer.

25. The method of claim 21, wherein the substrate further comprises one or more of diamond, aluminum nitride, boron nitride, graphite, sapphire, silicon, silicon dioxide, and silicon nitride.

26. The method of claim 21, wherein the single crystal seed layer further comprises one or more of aluminum nitride, silicon carbide, aluminum gallium nitride, indium gallium nitride, indium phosphide, and gallium arsenide.

27. The method of claim 21, wherein the epitaxial layer further comprises one or more of aluminum nitride, silicon carbide, aluminum gallium nitride, indium gallium nitride, indium phosphide, gallium arsenide, and gallium antimonide.

28. The method of claim 21, wherein the exfoliation layer further comprises one or more of helium and boron.

29. An epitaxial layer regrowth method, comprising:
depositing a single crystal seed layer on a support wafer, wherein the support wafer comprises an etch stop;
etching trenches in a portion of the single crystal seed layer and a portion of the etch stop;
bonding the single crystal seed layer, on the support wafer, to a substrate;
removing the support wafer and the etch stop layer leaving behind one or more single crystal seeds, generated from the single crystal seed layer, on the substrate;
growing a first epitaxial layer on the substrate from the single crystal seeds; and
growing a device layer on the grown first epitaxial layer.

30. The method of claim 29, further comprises:
growing a second epitaxial layer on the first epitaxial layer.

31. The method of claim 29, wherein growing the device layer comprises:
growing an epitaxial layer forming one or more of a field effect transistor, a light emitting diode, a laser diode, and a photodetector.

32. The method of claim 29, further comprises:
bonding a single crystal silicon layer to the device layer;
fabricating complementary metal oxide semiconductor devices on the bonded single crystal silicon layer.

33. The method of claim 29, wherein the substrate is one of a polycrystalline and a single crystalline.

34. The method of claim 29, further comprising:
forming an electrically insulating bond interface between the substrate and the one or more single crystal seeds.

35. The method of claim 29, further comprising:
forming an electrically conducting bond interface between the substrate and the one or more single crystal seeds.

36. The method of claim 29, wherein the substrate includes a layer comprising one or more of silicon carbide, diamond, gallium nitride, aluminum nitride, boron nitride, graphite, sapphire, silicon, silicon dioxide, and silicon nitride.

37. The method of claim 29, wherein the single crystal seed layer comprising one or more of gallium nitride, aluminum nitride, silicon carbide, aluminum gallium nitride, indium gallium nitride, indium phosphide, and gallium arsenide.

38. The method of claim 29, wherein the first epitaxial layer comprises one or more of gallium nitride, aluminum nitride, indium nitride, silicon carbide, indium phosphide, gallium arsenide, and gallium antimonide.

39. The method of claim 29, wherein the exfoliation layer comprising one or more of helium, boron, and hydrogen.

40. The method of claim 29, wherein in the removing, only the support wafer is removed leaving behind the etch stop layer and the one or more single crystal seeds on the substrate.
